(19) United States
(12) Patent Application Publication
(10) Pub. No.: US 2014/0091678 A1
(43) Pub. Date: Apr. 3, 2014

(54) LAMINATE

(71) Applicant: NGK Insulators, Ltd., Nagoya-City (JP)

(72) Inventors: Takaaki KOIZUMI, Tajimi-City (JP); Takashi EBIGASE, Nagoya-City (JP); Shinya TAKEMURA, Komaki-City (JP)

(73) Assignee: NGK Insulators, Ltd., Nagoya-City (JP)

(21) Appl. No.: 14/043,135

(22) Filed: Oct. 1, 2013

(30) Foreign Application Priority Data
Oct. 2, 2012 (JP) 2012-220296

(51) Int. Cl. H01L 41/08

(52) U.S. Cl. CPC H01L 41/0805
USPC 310/367

(57) ABSTRACT

A piezoelectric/electrostrictive film type element includes a lower electrode, a piezoelectric layer, and an upper electrode laminated in order on a support. An average particle diameter of each of particles of a piezoelectric material forming the piezoelectric layer falls within a range of 0.5 μm to 10 μm. The sectional shape of the piezoelectric layer is a “quadrilateral (substantially rectangular shape) having a height of from 0.5 μm to 15 μm and an angle (θ) at an end point of a base of from 85° to 105°.” A surface roughness of a side surface of the piezoelectric layer is 0.05 dμm to 0.5 dμm at the maximum height roughness Rz (defined by JIS B 0601:2001). Both “generation of a leak current that flows through the piezoelectric layer” and “occurrence of particle shedding from a side surface of the piezoelectric layer” can be prevented.

### BACKGROUND OF THE INVENTION

1. Field of the Invention

The present invention relates to a “laminate including a lower electrode, a dielectric layer, and an upper electrode,” which is formed on a support, and more particularly, to a laminate that includes a piezoelectric layer as a dielectric layer and functions as a piezoelectric/electrostrictive film type element.

2. Description of the Related Art

Hitherto, there has been widely known a piezoelectric/electrostrictive film type element that is a laminate including a plate-like lower electrode formed on a support, a piezoelectric layer that is a fired body formed on the lower electrode, and a plate-like upper electrode formed on the piezoelectric layer so as to be opposed in parallel to the lower electrode (see, for example, Japanese Patent Application Laid-open No. 2010-219153). Such a piezoelectric/electrostrictive film type element is widely used as, for example, a drive source of an ink jet head (part for ejecting, in an atomized manner, liquid stored inside a pressure chamber in the support) of an ink jet printer.

Japanese Patent Application Laid-open No. 2010-219153 discloses, referring to FIG. 8, etc., a technology involving forming the sectional shape of the piezoelectric layer in its thickness direction into a “trapezoid that has a lower base corresponding to an interface with respect to the lower electrode, which is longer than an upper base corresponding to an interface with respect to the upper electrode.” Japanese Patent Application Laid-open No. 2010-219153 describes that the following action and effect are provided with this structure. That is, when the sectional shape of the piezoelectric layer is a “trapezoid that expands toward the lower electrode side,” because, for example, the side surface of the piezoelectric layer is inclined so that the skirt thereof is expanded with respect to the upper surface of the lower electrode, stress hardly concentrates at a “peripheral edge portion of the side surface of the piezoelectric layer, which is brought into contact with the lower electrode.” As a result, there hardly occurs a situation that the peripheral edge portion of the piezoelectric layer is separated from the lower electrode, and the drive efficiency of the piezoelectric/electrostrictive film type element may be prevented from being reduced by the separation.

### SUMMARY OF THE INVENTION

By the way, as described above, when the sectional shape of the piezoelectric layer is a “trapezoid that expands toward the lower electrode side,” the ratio of the area of the upper electrode to the area of the lower electrode (when viewed from above) decreases. As a result, the ratio of the “area of a part of the piezoelectric layer, which is sandwiched between the upper and lower electrodes (that is, a part relating to the drive)” to the “area of the lower electrode” (when viewed from above) decreases. This fact leads to reduction in drive efficiency of the piezoelectric/electrostrictive film type element.

To address this problem, it is conceivable to form the sectional shape of the piezoelectric layer into, instead of a “trapezoid,” a “rectangle” (or a shape close to a rectangle, hereinafter called a “substantially rectangular shape”), that is, a shape in which the side surface of the piezoelectric layer extends upwardly and (substantially) perpendicularly from the upper surface of the lower electrode. With this, (when viewed from above,) “the ratio of the area of the upper electrode to the area of the lower electrode,” that is, “the ratio of the area of the part of the piezoelectric layer, which is sandwiched between the upper and lower electrodes (that is, the part relating to the drive) to the area of the lower electrode” can be increased. In this manner, the drive efficiency of the piezoelectric/electrostrictive film type element can be improved.

However, when the sectional shape of the piezoelectric layer is a “rectangle” as described above, as compared to the case where the sectional shape is a “trapezoid,” a distance between upper and lower ends of the side surface of the piezoelectric layer (that is, a distance between end portions of the opposing upper and lower electrodes) is reduced. As a result, when a voltage is applied between the upper and lower electrodes, a leak current that flows through the piezoelectric layer is easily generated. When a large amount of leak current flows, there may arise problems in that the drive efficiency of the piezoelectric/electrostrictive film type element decreases, etc.

The inventors of the present invention assume the following dielectric layer. A dielectric layer (piezoelectric layer) that is a fired body included in a laminate such as the above-mentioned piezoelectric/electrostrictive film type element is formed so that a “shape that is represented by a virtual line obtained by approximating a contour of a sectional shape in a thickness direction of the dielectric layer is a quadrilateral having a height of 0.5 μm or more and 15 μm or less and an angle at an end point of a base of 85° or more and 105° or less” (in other words, the sectional shape of the dielectric layer is a substantially rectangular shape having a height of 0.5 μm or more and 15 μm or less). Further, “the dielectric layer is formed of particles of a dielectric material, which each have an average particle diameter d of 0.5 μm or more and 10 μm or less.”

In this case, it is preferred that the length of the base of the rectangle be 30 μm or more and 500 μm or less. The quadrilateral may be a rectangle, a square, a trapezoid, or a parallelogram. Further, in a case where the shape of the laminate (piezoelectric/electrostrictive film type element) when viewed from above has a longitudinal direction, the sectional shape of the dielectric layer is a sectional shape in a “thickness direction of the dielectric layer” and a “direction perpendicular to the longitudinal direction.”

The inventors of the present invention have found that, in the laminate including the dielectric layer assumed as described above, the magnitude of the leak current is closely related to the surface roughness of the side surface of the dielectric layer. Specifically, the inventors of the present invention have found that, when the surface roughness of the side surface of the dielectric layer is 0.05 dμm or more at the maximum height roughness Rz, the leak current becomes significantly smaller as compared to a case with a different surface roughness (details are described later).

In addition, the inventors of the present invention have found that, when the surface roughness of the side surface of the dielectric layer is 0.5 dμm or less at the maximum height roughness Rz, as compared to a case with a different surface roughness, “particle shedding” (phenomenon that the particles forming the side surface fall from the side surface) from the side surface of the dielectric layer when a voltage is applied between the upper and lower electrodes (in particular, when the voltage is applied for a long period of time) is more significantly prevented (details are described later).

Based on the above-mentioned findings, the laminate according to one embodiment of the present invention has a feature in that the surface roughness of the side surface of the dielectric layer is 0.05 dμm or more and 0.5 dμm or less at the maximum height roughness Rz. With this, it is possible to prevent both of “generation of a leak current that flows through the dielectric layer” and “occurrence of ‘particle shedding’ from the side surface of the dielectric layer” when a voltage is applied between the upper and lower electrodes.

In the laminate according to one embodiment of the present invention, the dielectric layer is a piezoelectric layer that is a fired body formed of particles of a piezoelectric material. Therefore, when the laminate functions as a piezoelectric/electrostrictive film type element, it is preferred that the angle present at the end point of the base in the sectional shape of the piezoelectric layer be 90° or more and 105° or less.

In a case where the dielectric layer is a piezoelectric layer (therefore, in a case where the laminate is a piezoelectric/electrostrictive film type element), when a voltage is applied between the upper and lower electrodes at a predetermined pattern, the piezoelectric layer is driven, and as a result, the center portion of the piezoelectric/electrostrictive film type element (when viewed from above) is displaced in the up-down direction with respect to the peripheral edge portion (when viewed from above). The inventors of the present invention have found that, when the “angle” is 90° or more and 105° or less, as compared to the case where the “angle” is 85° or more and less than 90°, the level of the displacement (displacement amount) of the piezoelectric/electrostrictive film type element is significantly increased (details are described later).

Now, additional remarks are made of the dielectric layer (piezoelectric layer) of the laminate according to one embodiment of the present invention. The dielectric layer (piezoelectric layer) may be produced with use of a so-called “thin film method” such as sputtering and CVD, but is preferred to be produced with use of a so-called “thick film method” such as screen printing, spin coating, and tape casting. The “thick film method” as used herein refers to a method of forming a film of produced/synthesized powder (slurry) on a substrate, and firing the obtained compact to obtain a sintered film.

In order to set the average particle diameter of each of the particles of the dielectric material forming the dielectric layer to fall within the range of 0.5 μm to 10.0 μm, the dielectric layer is preferred to be produced with use of the so-called “thick film method.” When the dielectric layer is produced with use of the so-called “thin film method,” the average particle diameter of each of the particles becomes a value markedly smaller than values within this range.

Further, the entire region of the surface (except the side surface) of the dielectric layer (piezoelectric layer) of the laminate (piezoelectric/electrostrictive film type element) according to one embodiment of the present invention is a sintered surface formed of an aggregate of the plurality of particles of the dielectric material, which each have an average particle diameter of the above-mentioned range (surface formed by firing, surface that is not subjected to any additional processing after the firing). The side surface of the dielectric layer (piezoelectric layer) may be the sintered surface, or may be a surface (etched surface) that is formed (appears) by etching after the firing.

### BRIEF DESCRIPTION OF THE DRAWINGS

In the accompanying drawings:

FIG. 1 is a plan view illustrating a piezoelectric/electrostrictive film type element according to an embodiment of the present invention, which is provided at each of a plurality of positions on an upper surface of a support;

FIG. 2 is a sectional view taken along the line 2-2 of the piezoelectric/electrostrictive film type elements illustrated in FIG. 1;

FIGS. 3A to 3D are views illustrating first-half steps in a process of manufacturing the piezoelectric/electrostrictive film type elements illustrated in FIGS. 1 and 2;

FIGS. 4A to 4C are views illustrating second-half steps in the process of manufacturing the piezoelectric/electrostrictive film type elements illustrated in FIGS. 1 and 2;

FIG. 5 is a sectional view of a main part, for illustrating details of a piezoelectric layer illustrated in FIGS. 1 and 2; and

FIG. 6 is a view illustrating a quadrilateral (rectangle) represented by a virtual line obtained by approximating the contour of the sectional shape of the piezoelectric layer illustrated in FIG. 5.

### DETAILED DESCRIPTION OF THE PREFERRED EMBODIMENTS

(Configuration)

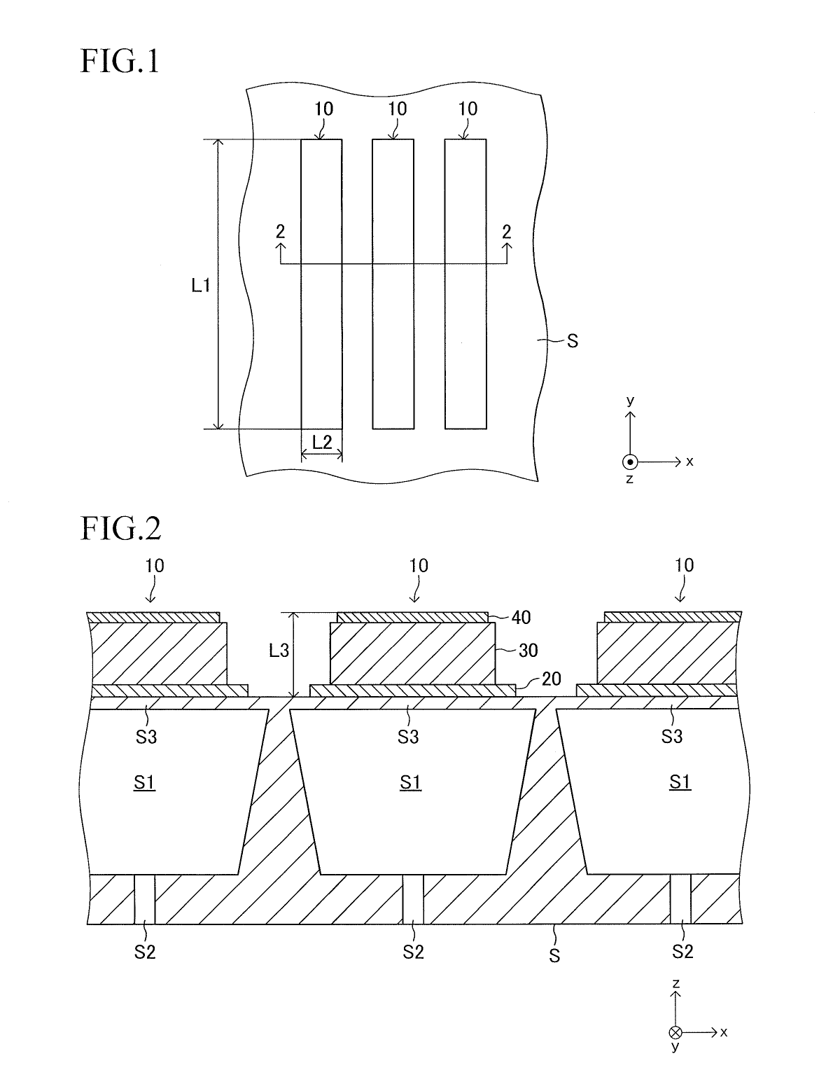

Now, the configuration of a piezoelectric/electrostrictive film type element according to an embodiment of the present invention is described with reference to the drawings. As illustrated in FIGS. 1 and 2, piezoelectric/electrostrictive film type elements 10 according to the embodiment of the present invention are formed on an upper surface of a support S at a plurality of positions so as to be arrayed at predetermined intervals. Each of the piezoelectric/electrostrictive film type elements 10 is used as a drive source of an ink jet head of an ink jet printer.

As illustrated in FIG. 1, when viewed from above (z-axis positive direction), each of the piezoelectric/electrostrictive film type elements 10 has a planar shape that is a rectangle having a longitudinal direction (y-axis direction). FIG. 2 illustrates a cross-section of the piezoelectric/electrostrictive film type elements 10 taken along a thickness direction (z-axis direction) and a “direction perpendicular to the longitudinal direction” (x-axis direction, hereinafter sometimes referred to as “lateral direction”). In the following, for the sake of easy understanding of the description, the cross-section taken along the thickness direction (z-axis direction) and the lateral direction (x-axis direction) (that is, a cross-section taken along an x-z plane) is called a “reference cross-section”.

As illustrated in FIG. 2, each of the piezoelectric/electrostrictive film type elements 10 includes a lower electrode 20 formed on the upper surface (flat surface) of the support S, a piezoelectric layer 30 formed on the lower electrode 20, and an upper electrode 40 formed on the piezoelectric layer 30 so as to be opposed in parallel to the lower electrode. A length (y-axis direction) L1 of the piezoelectric/electrostrictive film type element 10 is 500 μm to 5,000 μm, a width (x-axis direction) L2 thereof is 30 μm to 500 μm, and a height (z-axis direction) L3 thereof is 1 μm to 20 μm.

The support S is a fired body made of an electrically insulating material (for example, zirconia (ZrO₂)). At a position inside the support S corresponding to each of the piezoelectric/electrostrictive film type elements 10, a pressure chamber S1 is formed. On the lower side of the pressure chamber S1, an ejection nozzle S2 that communicates to the pressure chamber S1 and is opened on the lower side is formed. On the upper side of the pressure chamber S1, a vibration film S3 is formed. The vibration film S3 has a thin rectangular parallelepiped shape that extends in the longitudinal direction (y-axis direction) and has a thickness (z-axis direction) of 1 μm to 10 μm, a width (length in the x-axis direction) of 30 μm to 500 μm, and a length (y-axis direction) of 500 μm to 5,000 μm. Note that, the material for forming the support S is not limited to ceramics, and may be glass, a resin, or the like as long as the support S exhibits an electrically insulating property. Further, the material may be any one of single crystal, polycrystal, and amorphous.

The lower electrode 20 is a thin plate-like fired body made of an acid-resistant conductive material (for example, platinum (Pt)). Each of the lower electrodes 20 is formed on the upper surface of the corresponding vibration film S3 so that the entire lower electrode 20 is included in a range of the corresponding vibration film S3 when viewed from above. Each of the lower electrodes 20 has a thin rectangular parallelepiped shape that extends in the longitudinal direction (y-axis direction) and has a thickness (z-axis direction) of 0.1 μm to 10.0 μm, a width (length in the x-axis direction) of 30 μm to 500 μm, and a length (y-axis direction) of 500 μm to 5,000 μm. Note that, the material for forming the lower electrode 20 is not limited to a noble metal, and may be a conductive polymer, a conductive oxide, or the like as long as the lower electrode 20 exhibits an electrical conductivity.

The piezoelectric layer 30 is a fired body made of a polycrystalline piezoelectric material (for example, a lead zirconate titanate based material, in particular, lead zirconate titanate (PZT)). Each of the piezoelectric layers 30 is formed on the upper surface of the corresponding lower electrode 20 so that the entire piezoelectric layer 30 is included in a range of the corresponding lower electrode 20 when viewed from above. Each of the piezoelectric layers 30 has a thin plate shape that extends in the longitudinal direction (y-axis direction), and the reference cross-section thereof is a rectangle (alternatively, a shape close to a rectangle, hereinafter referred to as “substantially rectangular shape”). That is, the side surface of each of the piezoelectric layers 30 extends upwardly and (substantially) perpendicularly from the upper surface of the lower electrode 20. The piezoelectric layer 30 is described in detail later.

The upper electrode 40 is a thin plate-like fired body made of an acid-resistant conductive material (for example, gold (Au)). Each of the upper electrodes 40 is formed on the upper surface of the corresponding piezoelectric layer 30 so that the entire upper electrode 40 is included in a range of the corresponding piezoelectric layer 30 when viewed from above. Each of the upper electrodes 40 has a thin rectangular parallelepiped shape that extends in the longitudinal direction (y-axis direction) and has a thickness (z-axis direction) of 0.01 μm to 1.0 μm, a width (length in the x-axis direction) of 30 μm to 500 μm, and a length (y-axis direction) of 500 μm to 5,000 μm. Note that, the material for forming the upper electrode 40 is not limited to a noble metal, and may be a conductive polymer, a conductive oxide, or the like as long as the upper electrode 40 exhibits an electrical conductivity.

Now, the operation of the ink jet head illustrated in FIGS. 1 and 2 is simply described. Each of the pressure chambers S1 in the support S is filled with liquid (ink). When a voltage is applied between the upper and lower electrodes 20 and 40 of the piezoelectric/electrostrictive film type element 10 at a predetermined pattern, the piezoelectric layer 30 expands and contracts (mainly) in the x-y plane direction in accordance with the predetermined pattern. Due to the expansion and contraction of the piezoelectric layer 30, the center portion of the piezoelectric/electrostrictive film type element 10 (when viewed from above) is displaced in an up-down direction (z-axis direction) with respect to a peripheral edge portion thereof (when viewed from above). As a result, the corresponding vibration film S3 vibrates in the thickness direction (z-axis direction). In response to the vibration of the vibration film S3, the liquid stored in the corresponding pressure chamber S1 is ejected from the corresponding nozzle S2 in an atomized manner in accordance with the predetermined pattern.

(Manufacturing Method)

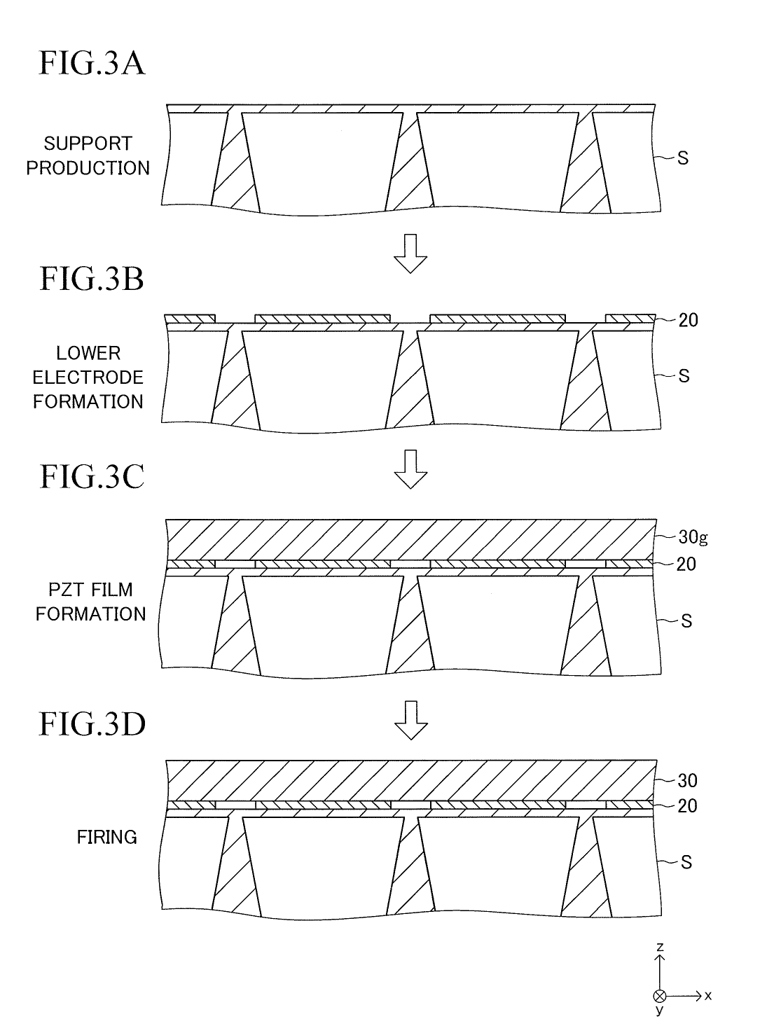

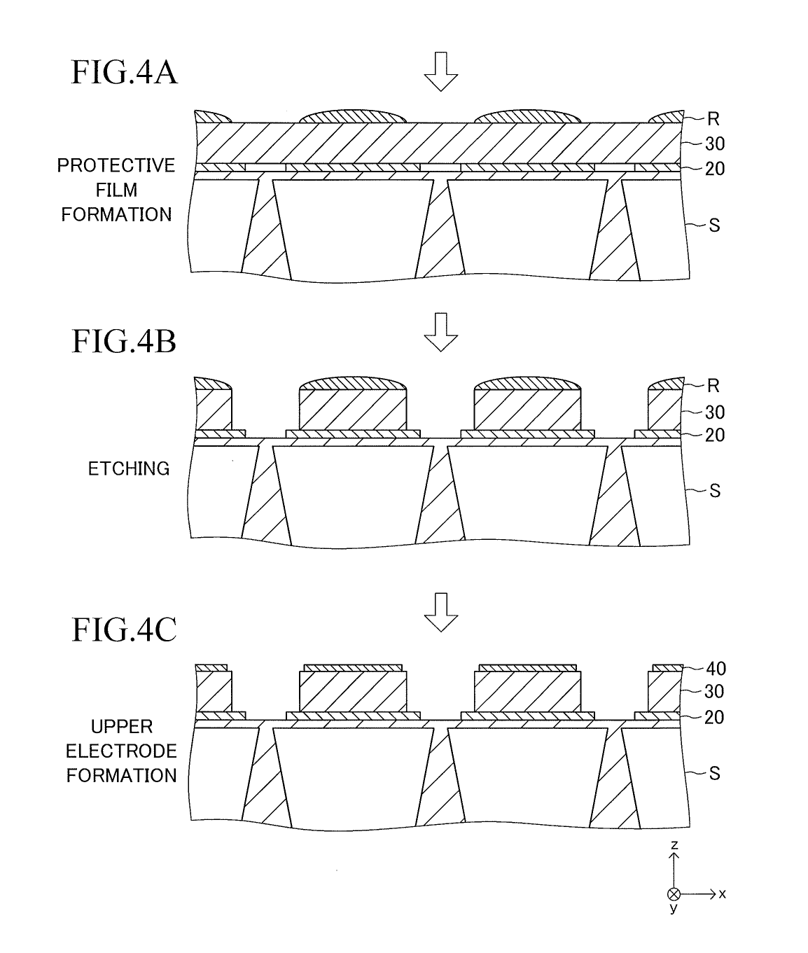

Next, a method of manufacturing the piezoelectric/electrostrictive film type element 10 described above is described with reference to FIGS. 3A to 3D and 4A to 4C.

First, as illustrated in FIG. 3A, the support S illustrated in FIGS. 1 and 2 is produced with use of a known method. Specifically, for example, a plurality of pieces of ZrO₂ tape in which corresponding patterns are respectively punched out are prepared, and those pieces of ZrO₂ tape are laminated. Then, this laminate is fired to produce the support S.

Subsequently, as illustrated in FIG. 3B, at “respective positions on the upper surface of the support S, which correspond to positions above the plurality of pressure chambers S1,” the lower electrodes 20 are formed with use of a known method. Specifically, for example, a photoresist (positive-type resist) is applied on the upper surface of the support S by spin coating or the like, to thereby form a photoresist film. This photoresist film is patterned by photolithography into a mask shape for obtaining the pattern of the respective lower electrodes 20. Subsequently, on the photoresist film patterned into the mask shape, for example, “slurry containing Pt powder” for the lower electrode 20 is applied by spin coating or the like. The film forming method is not particularly limited as long as the film has sufficient heat resistance to the firing temperature of the piezoelectric layer to be described later, and may be plating or sputtering. With this, the pattern of compacts for the respective lower electrodes 20 is obtained. After that, the photoresist film is removed, and the compacts are fired to form the respective lower electrodes 20. The firing temperature is 800° C. to 1,400° C., and the firing time period is 0.5 hours to 5.0 hours.

Next, as illustrated in FIG. 3C, on the upper surface of the support S having the plurality of lower electrodes 20 formed thereon, “slurry containing piezoelectric powder” is applied by spin coating or the like, to thereby form a film 30g for the piezoelectric layer 30. As the film forming method, alternatively, tape casting or the like may be employed. Note that, the suffix “g” of the reference symbol represents a “state before firing.” The thickness of the film 30g is adjusted so that the film may have a thickness required as the piezoelectric layer 30 (fired body) after “main firing” to be described later. The “slurry containing the piezoelectric powder” contains, for example, PZT+Bi(Ni_{2/3}Nb_{1/3})O₃ as the piezoelectric powder, powder of PbO and Bi₂O₃ as sintering aids, and in addition, a dispersant, an organic binder, and the like. The particle diameter of the powder is about 0.15 μm. After the film 30g is formed, the film 30g is subjected to dewaxing.

Subsequently, as illustrated in FIG. 3D, the film 30g is fired to form the film 30 (piezoelectric layer 30). The firing temperature is 1,000 ° C. and the firing time period is 2 hours.

Next, as illustrated in FIG. 4A, at “respective positions on the upper surface of the film 30 corresponding to the plurality of piezoelectric layers 30,” protective films R are formed with use of a known method. The protective films R are films that function as a mask when etching is performed as described later. Therefore, each of the protective films R is formed so as to match with the shape of the upper surface of the piezoelectric layer 30 to which the shape of the protective film R corresponds when viewed from above. As the protective films R, specifically, for example, a photoresist film is used. That is, a photoresist (positive-type resist) is applied on the upper surface of the sintered film 30 by spin coating or the like to form the photoresist film. As illustrated in FIG. 4A, this photoresist film is patterned by photolithography into a mask shape that corresponds to the shape of the upper surfaces of the respective piezoelectric layers 30, to thereby obtain the protective films R.

Subsequently, as illustrated in FIG. 4B, the film 30 is subjected to etching with use of an etchant for a piezoelectric material (for example, PZT). In this manner, the film 30 is patterned into the shape of the corresponding piezoelectric layers 30. Specifically, the etching was performed as follows.

As the etchant, one that contains acid as the main component was used. For example, an etchant obtained by doping, into dilute hydrochloric acid having a concentration of 10%, a trace of ammonium fluoride, a thickener, a complexing agent, a surfactant, etc. (fluorine concentration of less than 1%) was used. The etchant stored in a nozzle and the film 30 were heated and maintained at a temperature higher than room temperature (for example, about 40° C.). From an opening of a leading end portion of the nozzle directed downward (z-axis negative direction) at a position above the upper surface of the film 30 (position in the z-axis positive direction) by a predetermined distance (spraying distance, for example, 8 cm), the etchant was sprayed downward toward the upper surface of the film 30 (in particular, between adjacent protective films R and R) at a predetermined spraying pressure (for example, 0.2 MPa) for a predetermined spraying time period (for example, 2 minutes). After that, the etched film 30 was cleaned with pure water. Such spraying and cleaning were alternately performed by a predetermined number of times, and the etching was completed.

In this embodiment, the piezoelectric layer 30 obtained after the patterning is completed by etching has, in the reference cross-section, the above-mentioned “substantially rectangular shape,” that is, a “shape in which the side surface of the piezoelectric layer 30 extends upwardly and (substantially) perpendicularly from the upper surface of the lower electrode 20 (θ≈90° in FIG. 6 to be described later).” With this, the “ratio of the area of a part of the piezoelectric layer 30 sandwiched between the upper and lower electrodes (that is, a part relating to the drive) to the area of the lower electrode 20” can be increased, and the drive efficiency of the piezoelectric/electrostrictive film type element 10 can be improved.

In this case, when the etching rate (rate of removal of the film by etching) decreases as the etching progresses downward in the thickness direction of the film 30 (z-axis direction), the range in the x-axis direction of the film 30 in a part between the adjacent protective films R and R to be removed by etching is reduced as the etching progresses downward in the thickness direction of the film 30 (z-axis direction). As a result, the shape of the reference cross-section of the piezoelectric layer 30 is a “trapezoid in which the upper base is shorter than the lower base (θ<90°).” On the other hand, when the etching rate increases as the etching progresses downward in the thickness direction of the film 30 (z-axis direction), the range in the x-axis direction of the film 30 to be removed by etching increases as the etching progresses downward in the thickness direction of the film 30 (z-axis direction). As a result, the shape of the reference cross-section of the piezoelectric layer 30 is a “trapezoid in which the upper base is longer than the lower base (θ>90°).” Therefore, in order to form the shape of the reference cross-section of the piezoelectric layer 30 into the above-mentioned “substantially rectangular shape” (θ≈90°), the etching rate needs to be adjusted to be substantially constant in the thickness direction of the film 30 (z-axis direction).

The etching rate may be adjusted by controlling, for example, the concentration of the etchant, the spraying distance, the spraying pressure, the spraying time period, the opening diameter of the nozzle, and the temperature of the etchant and the film 30. Specifically, the etching rate increases as the concentration of the etchant is higher, the spaying distance is shorter, the spraying pressure is higher, the spraying time period is longer, the opening diameter of the nozzle is larger, and the temperature of the etchant and the film 30 is higher.

In this embodiment, as described above, the etching rate is adjusted to be substantially constant in the thickness direction of the film 30 (z-axis direction). In this manner, the angle θ is adjusted to fall within a range of 85° to 105°. After the etching of the film 30 is completed, the respective protective films R are removed, and the film 30 is subjected to dewaxing.

Then, as illustrated in FIG. 4C, on the upper surfaces of the respective piezoelectric layers 30, the upper electrodes 40 are formed with use of a known method, respectively. Specifically, for example, on each of the upper surfaces of the piezoelectric layers 30, a photoresist (positive-type resist) is applied by spin coating or the like, to thereby form a photoresist film. The photoresist film is patterned by photolithography into a mask shape for obtaining a pattern of the corresponding upper electrode 40. Subsequently, on each of the photoresist films patterned into the mask shape, for example, “slurry containing Au powder” for the upper electrode 40 is applied by spin coating or the like. The material and method to be used to form the upper electrode 40 are not particularly limited as long as the material and method enable the upper electrode to achieve a sufficient function. That is, a metal other than Au may be used as the material, an “organometallic compound such as resinate” may be used as the slurry, and plating and sputtering may be used as the forming method. With this, the pattern of compacts for the respective upper electrodes 40 is obtained. After that, the photoresist film is removed, the compacts are fired, and thus the respective upper electrodes 40 are formed. The firing temperature is 400° C. to 1,000° C., and the firing time period is 1 minute to 2 hours.

As described above, as illustrated in FIGS. 1 and 2, the plurality of piezoelectric/electrostrictive film type elements 10 (fired bodies) are formed on the support S. As described above, each of the piezoelectric layers 30 (fired body) may be produced easily with use of a so-called “thick film method” such as spin coating and tape casting.

(Feature of Piezoelectric Layer)

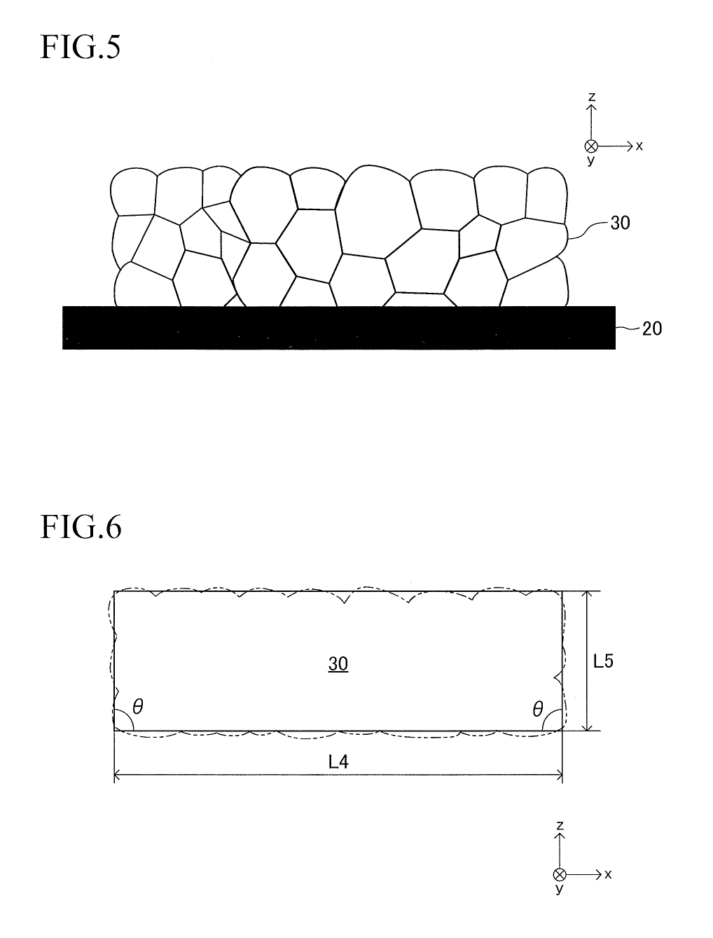

Next, the feature of the piezoelectric layer 30 (fired body) of the piezoelectric/electrostrictive film type element 10 formed by the above-mentioned manufacturing method is described with reference to FIGS. 5 and 6. Note that, for the sake of easy understanding of the description, in FIGS. 5 and 6, the piezoelectric/electrostrictive film type element 10 is represented in a form in which the upper electrode 40 is not formed on the upper surface of the piezoelectric layer 30. Further, in FIGS. 5 and 6, the piezoelectric/electrostrictive film type element 10 is illustrated in a compressed manner in the lateral direction (x-axis direction) (in an exaggerated manner in the vertical direction (z-axis direction)).

FIG. 5 is an example of the reference cross-section of the piezoelectric/electrostrictive film type element 10, which is obtained by cutting the piezoelectric/electrostrictive film type element 10 at an arbitrary position in the longitudinal direction (y-axis direction). As is understood from FIG. 5, it can be said that the piezoelectric layer 30 having the reference cross-section in a “substantially rectangular shape” is an aggregate obtained by assembling a plurality of particles of a piezoelectric material (PZT). Further, as described above, in a process of manufacturing the piezoelectric/electrostrictive film type element 10, after the piezoelectric layer 30 is fired, the surface of the piezoelectric layer 30 (except the side surface) is not subjected to any additional processing. In other words, the entire region of the surface of the piezoelectric layer 30 (except the side surface) is a sintered surface (surface formed by firing, surface that is not subjected to any additional processing after the firing). Therefore, an uneven surface is formed, in which parts corresponding to the plurality of particles are protruded and a part between adjacent particles is recessed. On the other hand, the side surface of the piezoelectric layer 30 is an etched surface (surface that is formed (appears) by etching after the firing, surface that is not subjected to any additional processing after the etching). Similarly to the above, the side surface is also an uneven surface in which parts corresponding to the plurality of particles are protruded and a part between adjacent particles is recessed.

The average particle diameter of each of the particles of the piezoelectric material, which are distributed inside the piezoelectric layer 30, is 0.5 μm to 10 μm. Note that, the particle diameter of a certain particle can be defined as a diameter of a circle having an area that is equal to an area of a region corresponding to the particle that can be recognized in the cross-section. The range of the average particle diameter of each of the above-mentioned particles of the piezoelectric material can be obtained with use of, for example, a plurality of reference cross-sections obtained by cutting the piezoelectric layer 30 at different positions in the longitudinal direction (y-axis direction). For example, the lower limit value of the range of the average particle diameter of each of the particles of the piezoelectric material described above is the minimum value of the average particle diameters obtained from the respective reference cross-sections, and the upper limit value of the range of the average particle diameter of each of the particles of the piezoelectric material described above is the maximum value of the average particle diameters obtained from the respective reference cross-sections. The average particle diameter of each of the particles of the piezoelectric material forming the piezoelectric layer 30 ranges from 0.5 μm to 10 μm. This is based on the fact that the piezoelectric layer 30 is produced with use of a so-called “thick film method” such as spin coating and tape casting. When the piezoelectric layer is produced by a so-called “thin film method,” the average particle diameter of each of the particles becomes a value that is markedly smaller than values within this range.

FIG. 6 illustrates the contour of the reference cross-section shape (substantially rectangular shape) of the piezoelectric layer 30 illustrated in FIG. 5 by a thin two-dot chain line, and illustrates the virtual line (substantially rectangular shape) obtained by approximating the contour line (two-dot chain line) by a thick solid line. The virtual line can be obtained as follows, for example. That is, the above-mentioned contour line (substantially rectangular shape) is divided into four parts corresponding to the upper side, the lower side, and the two lateral sides of the rectangle. Then, for each of the parts, based on a large number of points located on the contour line included in the corresponding part, the approximation straight line is obtained with use of a least squares method or the like. By connecting the four approximation straight lines obtained as described above, the above-mentioned virtual line (substantially rectangular shape) can be obtained.

The substantially rectangular shape represented by the virtual line obtained as described above has a lower-side length L4 of 30 μm to 500 μm and a height L5 of 0.5 μm to 15 μm. As described above, the angle θ at the end point of the lower side is 85° to 105°. The lower limit value of the range of each of the above-mentioned length, height, and angle is the minimum value of the minimum values of each of the length, height, and angle obtained from the above-mentioned plurality of reference cross-sections, or an average value of the respective minimum values. The upper limit value of the range of each of the above-mentioned length, height, and angle is the maximum value of the maximum values of each of the length, height, and angle obtained from the above-mentioned plurality of reference cross-sections, or an average value of the respective maximum values. Note that, the above-mentioned ranges of L4 and L5 are ranges that are suitable for the demand for, in the case where the piezoelectric/electrostrictive film type element 10 is used as a drive source of an ink jet head of an ink jet printer, appropriately jetting fine ink droplets from the ink jet head. When the piezoelectric/electrostrictive film type element 10 is used for other applications, the ranges of L4 and L5 are not limited to the above-mentioned ranges, and may be set to ranges appropriate for those applications.

(Prevention of Leak Current and Particle Shedding from Side Surface of Piezoelectric Layer)

As described above, in this embodiment, the following piezoelectric layer is assumed. The piezoelectric layer 30 of the piezoelectric/electrostrictive film type element 10 has a “shape that is represented by the virtual line, the shape being a quadrilateral having the length L4 of 30 μm to 500 μm, the height L5 of 0.5 μm to 15 μm, and the angle θ of 85° to 105°” (in other words, the sectional shape of the piezoelectric layer 30 is a substantially rectangular shape having a length of 30 μm to 500 μm and a height of 0.5 μm to 15 μm). Further, “the average particle diameter d of each of the particles of the piezoelectric material forming the piezoelectric layer 30 is 0.5 μm to 10 μm.”

In the piezoelectric/electrostrictive film type element 10 including the piezoelectric layer 30 having an extremely small thickness as described above, when a voltage is applied between the upper and lower electrodes 20 and 40, a leak current that flows through the piezoelectric layer 30 is easily generated. When an amount of the leak current is large, there easily occur problems such as reduction in drive efficiency of the piezoelectric/electrostrictive film type element 10.

The inventors of the present invention have worked on various experiments and the like to prevent the above-mentioned leak current. As a result, the inventors of the present invention have found that the magnitude of the above-mentioned leak current is closely related to the surface roughness of the side surface of the piezoelectric layer 30. Specifically, the inventors of the present invention have found that, when the average particle diameter of the piezoelectric material is set in the order of “d”μm, the leak current becomes significantly smaller in a case where the surface roughness of the side surface of the piezoelectric layer 30 is 0.05 dμm or more at the maximum height roughness Rz (defined by JIS B 0601:2001) as compared to a case with a different surface roughness. In the following, the testing that confirms this fact is described.

(Testing)

In this testing, a plurality of samples of the piezoelectric/electrostrictive film type element 10 were produced in accordance with the procedure illustrated in FIGS. 3A to 3D and FIGS. 4A to 4C. The plurality of samples had different combinations of a piezoelectric material, the width (layer width) L4 of the piezoelectric layer 30 (see FIG. 6), the thickness (layer thickness) L5 of the piezoelectric layer 30 (see FIG. 6), the average particle diameter d of the piezoelectric material, the angle θ (see FIG. 6), and the surface roughness of the side surface of the piezoelectric layer 30. Specifically, as shown in Table 1, 24 types of levels (combinations) were prepared. 10 samples (N=10) were produced for each level.

TABLE 1

| | | Layer | Layer | Average | | Surface | Displacement | Leak |
|---|---|---|---|---|---|---|---|---|
| | | width L4 | thickness L5 | particle | Angle θ | roughness Rz | amount | current |
| Level | Material | [μm] | [μm] | diameter d | [°] | [μm] | [μm] | [μA] |
| 1 | PZT | 70 | 3 | 2 | 105 | 0.31(0.155d) | 0.320 | 0.15 |
| 2 | PZT | 70 | 3 | 2 | 97 | 0.30(0.15d) | 0.310 | 0.14 |
| 3 | PZT | 70 | 3 | 2 | 95 | 0.32(0.16d) | 0.305 | 0.13 |
| 4 | PZT | 70 | 3 | 2 | 93 | 0.31(0.155d) | 0.305 | 0.13 |
| 5 | PZT | 70 | 3 | 2 | 90 | 0.30(0.15d) | 0.298 | 0.12 |
| 6 | PZT | 70 | 3 | 2 | 87 | 0.33(0.165d) | 0.263 | 0.13 |
| 7 | PZT | 70 | 3 | 2 | 86 | 0.31(0.155d) | 0.260 | 0.13 |
| 8 | PZT | 70 | 3 | 2 | 85 | 0.30(0.15d) | 0.263 | 0.13 |
| 9 | PZT | 70 | 3 | 2 | 95 | 0.05(0.025d) | 0.304 | 2.03 |
| 10 | PZT | 70 | 3 | 2 | 93 | 0.07(0.035d) | 0.304 | 1.14 |
| 11 | PZT | 70 | 3 | 2 | 94 | 0.11(0.055d) | 0.304 | 0.22 |
| 12 | PZT | 70 | 3 | 2 | 95 | 0.32(0.16d) | 0.305 | 0.13 |
| 13 | PZT | 70 | 3 | 2 | 95 | 0.45(0.225d) | 0.306 | 0.11 |
| 14 | PZT | 70 | 3 | 2 | 96 | 0.53(0.265d) | 0.309 | 0.10 |
| 15 | PZT | 70 | 3 | 2 | 95 | 0.98(0.49d) | 0.305 | 0.07 |
| 16 | PZT | 30 | 0.5 | 1 | 88 | 0.08(0.08d) | 0.156 | 0.12 |
| 17 | PZT | 30 | 0.5 | 1 | 92 | 0.11(0.11d) | 0.228 | 0.11 |
| 18 | PZT | 30 | 0.5 | 1 | 97 | 0.09(0.09d) | 0.235 | 0.13 |
| 19 | PZT | 180 | 3 | 0.5 | 91 | 0.07(0.14d) | 0.222 | 0.13 |
| 20 | PZT | 180 | 3 | 0.5 | 99 | 0.15(0.3d) | 0.245 | 0.09 |
| 21 | PZT | 180 | 3 | 0.5 | 105 | 0.21(0.42d) | 0.253 | 0.08 |
| 22 | PZT | 500 | 15 | 10 | 86 | 0.17(0.017d) | 0.354 | 3.33 |
| 23 | PZT | 500 | 15 | 10 | 95 | 0.52(0.052d) | 0.407 | 0.25 |
| 24 | PZT | 500 | 15 | 10 | 103 | 1.33(0.133d) | 0.415 | 0.15 |

In each of the samples, the layer width and the layer thickness are adjusted by adjusting the width and the thickness of the film 30g for the piezoelectric layer 30 (see FIG. 3C). The average particle diameter is adjusted by adjusting the particle diameter of the piezoelectric powder contained in the slurry for the film 30g, the firing temperature, and the firing time period. The angle θ is adjusted by, as described above, adjusting the etching rate in the thickness direction of the film 30 (z-axis direction). Further, the surface roughness of the side surface of the piezoelectric layer 30 is adjusted by, for example, adjusting the above-mentioned “etchant spraying time period.” Specifically, as the “spraying time period” is longer, the surface roughness increases. This is based on the following reason. That is, generally, when an uneven surface is subjected to etching, the etching rate is larger in a concave portion than in a convex portion. Therefore, as the “spraying time period” (that is, a time period in which the surface is continuously exposed to the etchant) is longer, the degree of unevenness of the surface tends to increase. On the other hand, as described above, the side surface of the piezoelectric layer 30 is an uneven surface in which the parts corresponding to the plurality of particles are protruded and the part between the adjacent particles is recessed. In view of the above-mentioned point, as the “etchant spraying time period” is longer, the surface roughness of the piezoelectric layer 30 increases. Note that, the surface roughness was measured with use of a white-light interference type non-contact profilometer (manufactured by Canon Inc.: ZYGO NewView 7300).

Further, as is understood from Table 1, each of the samples has the width L4 (see FIG. 6) of from 30 μm to 500 μm, the height L5 (see FIG. 6) of from 0.5 μm to 15 μm, the angle θ (see FIG. 6) of from 85° to 105°, and the average particle diameter d of the piezoelectric material of from 0.5 μm to 10 μm.

Each of the produced samples was subjected to “polarization treatment” at a temperature of 75° C., a voltage corresponding to a DC electric field of 15 kV/mm, and a voltage application time period of 10 seconds. After that, the leak current between the upper and lower electrodes was evaluated with respect to each of the samples under a high humidity situation with humidity of 85%. Specifically, in the leak current evaluation, the maximum leak current value when an electric field of 30 kV/mm was applied between the upper and lower electrodes was measured. The results (average values of the samples (N=10) for respective levels) are shown in Table 1.

As is understood from levels 1 to 24 (in particular, levels 9 to 15) of Table 1, as the surface roughness of the side surface of the piezoelectric layer 30 becomes larger, the leak current value tends to decrease. This reason is considered as follows. As the surface roughness increases, a “distance (passage) between the upper and lower ends of the side surface of the piezoelectric layer 30 in a case considering fine irregularities as well,” that is, “the passage through which the electron flows between the end portions of the opposing upper and lower electrodes” becomes long. Further, when the surface roughness is 0.05 dμm or more at the maximum height roughness Rz (see levels other than levels 9, 10, and 22), the leak current becomes significantly smaller as compared to a case with a different surface roughness (when the surface roughness is less than 0.05 dμm) (see levels 9, 10, and 22).

Further, for each of the samples, the displacement amount of the piezoelectric/electrostrictive film type element 10 when an electric field having a pattern of a triangular wave of 1 Hz and having an electric field intensity of 10 kV/mm was applied was measured. The displacement amount was measured by measuring the displacement amount in the up-down direction (z-axis direction) at the center portion of the upper surface of the piezoelectric/electrostrictive film type element 10 by a laser Doppler displacement meter. The results (average values of the samples (N=10) for respective levels) are also shown in Table 1.

As is understood from levels 1 to 24 (in particular, levels 1 to 8) of Table 1, it can be said that, when the angle θ is 90° to 105° (see levels other than levels 6 to 8, 16, and 22), as compared to the case where the angle θ is 85° or more and less than 90° (see levels 6 to 8, 16, and 22), the displacement amount of the piezoelectric/electrostrictive film type element 10 is significantly larger. The reason is considered as follows. When the angle θ is 90° to 105°, as compared to the case where the angle θ is 85° or more and less than 90°, the “ratio of the area of a part of the piezoelectric layer 30, which is sandwiched between the upper and lower electrodes (that is, a part relating to the drive) to the area of the lower electrode 20” can be increased, and thus the drive efficiency of the piezoelectric/electrostrictive film type element 10 can be improved.

In addition, evaluation was performed of whether or not “particle shedding” (phenomenon that the particles forming the side surface fall from the side surface) occurred from the side surface of the piezoelectric layer 30 when an electric field was applied for a long period of time at a pattern similar to that when the above-mentioned “displacement amount” was measured (that is, a pattern of a triangular wave of 10 kV/mm and 1 Hz). As a result (not shown in Table 1), it was found that, when the surface roughness of the side surface of the piezoelectric layer 30 was 0.5 dμm or less at the maximum height roughness Rz, as compared to a case with a different surface roughness (when the surface roughness was more than 0.5 dμm), the “particle shedding” from the side surface of the piezoelectric layer 30 was more significantly prevented.

As described above, the following has been found. The piezoelectric layer 30 of the piezoelectric/electrostrictive film type element 10 is formed so that a “sectional shape that is represented by the virtual line (see FIG. 6) is a quadrilateral having the length L4 of 30 μm to 500 μm, the height L5 of 0.5 μm to 15 μm, and the angle θ of 85° to 105° ” (in other words, the shape of the reference cross-section of the piezoelectric layer 30 is a substantially rectangular shape having a length of 30 μm to 500 μm and a height of 0.5 μm to 15 μm). Further, “the piezoelectric layer 30 is formed of particles of a piezoelectric material, which each have an average particle diameter d of 0.5 μm to 10 μm.” When the above-mentioned piezoelectric layer is used, by adjusting the surface roughness of the side surface of the piezoelectric layer 30 to fall within a range of 0.05 dμm to 0.5 dμm at the maximum height roughness Rz, it is possible to prevent both of “generation of a leak current that flows through the piezoelectric body” and “occurrence of ‘particle shedding’ from the side surface of the piezoelectric layer” when a voltage is applied between the upper and lower electrodes.

In the above, description is made of the case where the “dielectric layer” according to the present invention is the piezoelectric layer 30, and the “laminate” according to the present invention is the piezoelectric/electrostrictive film type element 10. However, the following fact has been separately confirmed. Also in a case where the “dielectric layer” according to the present invention is a dielectric layer other than the piezoelectric layer (for example, a layer made of a dielectric material such as barium titanate or strontium titanate), similarly to the above, the dielectric layer is formed so that the “shape that is represented by the virtual line (see FIG. 6) is a quadrilateral having the length L4 of 30 μm to 500 μm, the height L5 of 0.5 μm to 15 μm, and the angle θ of 85° to 105°.” Further, “the dielectric layer is formed of particles of a dielectric material, which each have an average particle diameter d of 0.5 μm to 10 μm.” When the above-mentioned dielectric layer is used, by adjusting the surface roughness of the side surface of the dielectric layer to fall within a range of 0.05 dμm to 0.5 dμm at the maximum height roughness Rz, it is possible to prevent both of “generation of a leak current that flows through the dielectric body” and “occurrence of ‘particle shedding’ from the side surface of the dielectric layer” when a voltage is applied between the upper and lower electrodes.

What is claimed is:

1. A laminate, comprising:
a lower electrode formed on a support;
a dielectric layer formed on the lower electrode; and
an upper electrode formed on the dielectric layer so as to be opposed in parallel to the lower electrode,
wherein the dielectric layer comprises a fired body, and the dielectric layer is formed of particles of a dielectric material, the particles each having an average particle diameter d of 0.5 μm or more and 10 μm or less,
wherein a shape of the dielectric layer, which is represented by a virtual line obtained by approximating a contour of a sectional shape in a thickness direction of the dielectric layer, is a quadrilateral having a height of 0.5 μm or more and 15 μm or less and an angle at an end point of a base of 85° or more and 105° or less, and
wherein the dielectric layer has a side surface with a surface roughness of 0.05 dμm or more and 0.5 dμm or less at a maximum height roughness Rz.

2. A laminate according to claim 1,
wherein the dielectric layer comprises a piezoelectric layer that is a fired body formed of particles of a piezoelectric material, and
wherein the laminate functions as a piezoelectric/electrostrictive film type element.

3. A laminate according to claim 2, wherein the angle at the end point of the base in the sectional shape of the piezoelectric layer is 90° or more and 105° or less.
